(19) United States
(12) Patent Application Publication
(10) Pub. No.: US 2026/0181780 A1
(43) Pub. Date: Jun. 25, 2026

(54) ELECTRONIC DEVICE

(71) Applicant: Innolux Corporation, Miaoli County (TW)

(72) Inventors: Yi-Hua Hsu, Miaoli County (TW); Ming-Chun Tseng, Miaoli County (TW); Hao-Jung Huang, Miaoli County (TW); Li-Wei Mao, Miaoli County (TW)

(73) Assignee: Innolux Corporation, Miaoli County (TW)

(21) Appl. No.: 19/403,208

(22) Filed: Nov. 27, 2025

Related U.S. Application Data
(60) Provisional application No. 63/737,798, filed on Dec. 23, 2024.

(30) Foreign Application Priority Data
Aug. 11, 2025 (CN) 202511119211.1

(51) Int. Cl. H05K 1/14

(52) U.S. Cl. CPC H05K 1/144; H05K 2201/042

(57) ABSTRACT

An electronic device includes a circuit substrate, a first substrate, an electronic element, a drive unit, and an internal electrical connection structure. The first substrate overlaps the circuit substrate. The electronic element is disposed on the first substrate. The drive unit is disposed on the first substrate and electrically connected to the electronic element. The internal electrical connection structure is disposed between the circuit substrate and the first substrate and includes a first conductive terminal and a second conductive terminal, in which the first conductive terminal and the second conductive terminal are electrically connected to the first substrate and the circuit substrate, respectively.

### CROSS-REFERENCE TO RELATED APPLICATION

This application claims the priority benefits of U.S. provisional application serial no. 63/737,798, filed on December 23, 2024, and China application serial no. 202511119211.1, filed on August 11, 2025. The entirety of each of the above-mentioned patent applications is hereby incorporated by reference herein and made a part of this specification.

### BACKGROUND

For electronic devices including multiple substrates, it is necessary to develop an electrical connection manner between the multiple substrates.

### BRIEF DESCRIPTION OF THE DRAWINGS

FIG. 1 is a partial schematic top view of an electronic device according to some embodiments of the disclosure.

FIG. 2 is a simple circuit diagram of a drive unit in FIG. 1.

FIG. 3 is a partial schematic cross-sectional view of the electronic device corresponding to a section line I-I' in FIG. 1 before and after assembly.

FIG. 4 to FIG. 9 are partial schematic cross-sectional views of electronic devices before and after assembly according to other embodiments of the disclosure, respectively.

### DESCRIPTION OF THE EMBODIMENTS

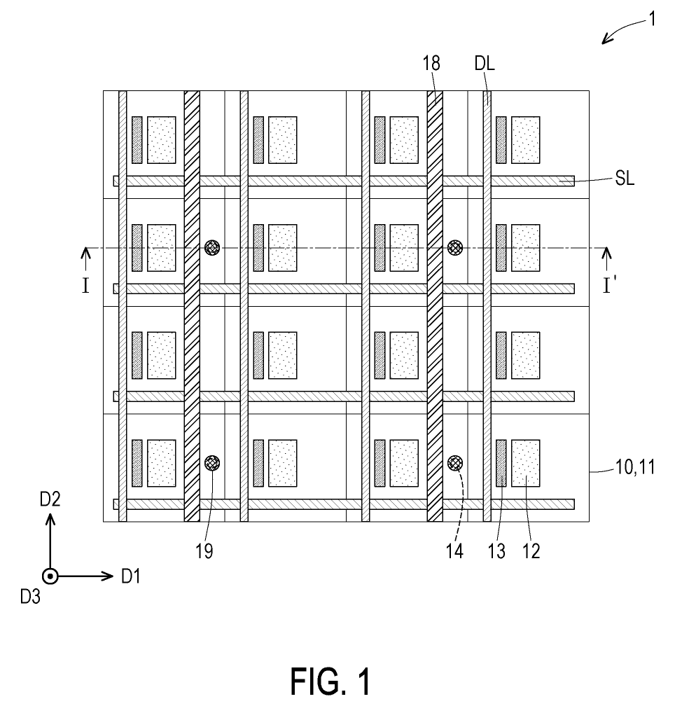

Referring to FIG. 1 to FIG. 3 first, an electronic device 1 may include a circuit substrate 10, a first substrate 11, an electronic element 12, a drive unit 13, and an inner electrical connection structure 14. The first substrate 11 overlaps the circuit substrate 10. The electronic element 12 is disposed on the first substrate 11. The drive unit 13 is disposed on the first substrate 11 and electrically connected to the electronic element 12. The inner electrical connection structure 14 is disposed between the circuit substrate 10 and the first substrate 11 and includes a first conductive terminal 141 and a second conductive terminal 142, in which the first conductive terminal 141 and the second conductive terminal 142 are electrically connected to the first substrate 11 and the circuit substrate 10, respectively.

The circuit substrate 10 may be a printed circuit board (PCB). The first substrate 11 is disposed overlapping with the circuit substrate 10 in a thickness direction (for example, a direction D3) of the electronic device 1. Although not illustrated, the first substrate 11 may include a substrate. The substrate may be a rigid substrate or a flexible substrate. The material of the substrate includes, for example, glass, quartz, ceramic, sapphire, or plastic, but not limited thereto.

The substrate may be a light-transmitting substrate, a semi-light-transmitting substrate, or a non-light-transmitting substrate. If the electronic element 12 is a light-emitting component, and the electronic element 12 is disposed between the first substrate 11 and the circuit substrate 10, the substrate may use a light-transmitting substrate or a semi-light-transmitting substrate, so that light emitted by the light-emitting component can penetrate the first substrate 11. If the electronic element 12 is a light-emitting component, and the first substrate 11 is disposed between the electronic element 12 and the circuit substrate 10, the substrate may use a light-transmitting substrate, a semi-light-transmitting substrate, or a non-light-transmitting substrate. If the electronic element 12 is not a light-emitting component, the substrate may use a light-transmitting substrate, a semi-light-transmitting substrate, or a non-light-transmitting substrate.

Although not illustrated, the first substrate 11 may further include a wiring layer. The wiring layer is disposed on the substrate and disposed between the electronic element 12 and the substrate. The wiring layer may include multiple conductive layers and multiple insulating layers. For example, the wiring layer may include a first conductive layer, a second conductive layer, and one or more insulating layers disposed between the first conductive layer and the second conductive layer, in which the first conductive layer may include multiple scan lines SL (FIG. 1), and the second conductive layer may include multiple data lines DL (FIG. 1).

As shown in FIG. 1, the multiple scan lines SL may extend along the direction D1 and be arranged along a direction D2. The direction D1 and the direction D2 intersect each other and are, for example, perpendicular to each other, but not limited thereto. The multiple data lines DL may extend along the direction D2 and be arranged along the direction D1.

The electronic element 12 is disposed on the first substrate 11 and electrically connected to the wiring layer of the first substrate 11. The electronic element 12 may be disposed on the first substrate 11 through flip chip bonding, wire bonding, or other methods. Alternatively, the electronic element 12 may be formed on the first substrate 11 through a panel process or a semiconductor process. Optionally, the electronic element 12 may share one or more conductive layers with the wiring layer of the first substrate 11, and/or share one or more insulating layers.

The electronic element 12 may include passive components and active components, such as capacitors, resistors, inductors, diodes, transistors, and the like. The diodes may include light-emitting diodes (LEDs), varactor diodes, or photodiodes. The LEDs may, for example, include OLED, mini LEDs, micro LEDs, or quantum dot LEDs, but not limited thereto.

In some embodiments, as shown in FIG. 1, the electronic device 1 may include multiple electronic elements 12, and the multiple electronic elements 12 are, for example, arranged in an array along the direction D1 and the direction D2. The multiple electronic elements 12 may, for example, be multiple light-emitting diodes, and the electronic device 1 may be a display device. For example, the multiple electronic elements 12 may serve as display pixels or backlight of the electronic device 1, but not limited thereto.

The drive unit 13 is disposed on the first substrate 11 and may be electrically connected to the electronic element 12 through the wiring layer of the first substrate 11. The drive unit 13 may be disposed on the first substrate 11 through flip chip bonding, wire bonding, or other methods. Alternatively, the drive unit 13 may be formed on the first substrate 11 through a panel process or a semiconductor process. Optionally, the drive unit 13 may share one or more conductive layers with the wiring layer of the first substrate 11, and/or share one or more insulating layers.

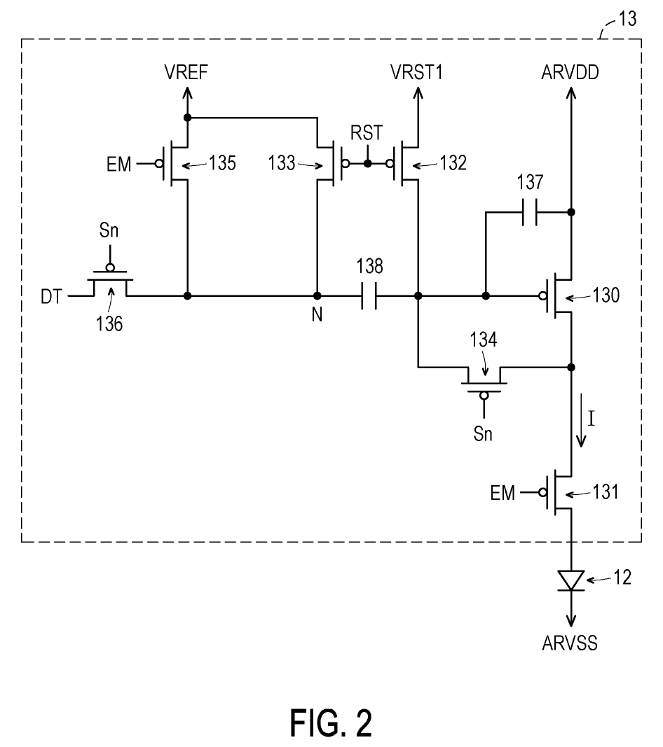

As shown in FIG. 1, the electronic device 1 may include multiple drive units 13. The drive units 13 may be electrically connected to the multiple electronic elements 12, respectively. For example, the drive units 13 and the electronic elements 12 may be disposed in a one-to-one manner, but not limited thereto. The drive unit 13 may include one or more active components and one or more passive components. FIG. 2 is an exemplary simplified circuit diagram of the drive unit 13. As an example, the electronic element 12 may be a light-emitting diode, and the drive unit 13 may include a drive transistor 130, a light-up transistor 131, a first reset transistor 132, a second reset transistor 133, a compensation transistor 134, a set transistor 135, a data transistor 136, a first capacitor 137, and a second capacitor 138. However, it should be understood that the respective numbers and types of active and passive components in the drive unit 13 may be changed, and are not limited to those shown in FIG. 2.

The light-up transistor 131 may be coupled between the drive transistor 130 and the electronic element 12, and receive a lighting signal EM. During a display period, the light-up transistor 131 is turned on to transmit a drive current I to the electronic element 12. The source of the light-up transistor 131 is coupled to the first source/drain of the drive transistor 130. The drain of the light-up transistor 131 is coupled to the electronic element 12. The anode of the electronic element 12 may be coupled to the light-up transistor 131. The cathode of the electronic element 12 may receive a second operating voltage ARVSS. The gate of the first reset transistor 132 may receive a reset signal RST. The first source/drain of the first reset transistor 132 may receive a first preset voltage VRST1. The second source/drain of the first reset transistor 132 may be coupled to the gate of the drive transistor 130. During a reset period, the first reset transistor 132 is turned on to transmit the first preset voltage VRST1 to the gate of the drive transistor 130. The gate of the second reset transistor 133 may receive the reset signal RST. The first source/drain of the second reset transistor 133 may receive a reference voltage VREF. The second source/drain of the second reset transistor 133 is coupled to a node N. During the reset period, the second reset transistor 133 is also turned on to transmit the reference voltage VREF to the node N. The compensation transistor 134 may be coupled between the gate of the drive transistor 130 and the first source/drain of the drive transistor 130, and receives a scan signal Sn. During a write period, the compensation transistor 134 is turned on, causing the drive transistor 130 to operate as a diode. The gate of the compensation transistor 134 receives the scan signal Sn, the source of the compensation transistor 134 is coupled to the gate of the drive transistor 130, and the drain of the compensation transistor 134 is coupled to the first source/drain of the drive transistor 130. The first terminal of the first capacitor 137 may be coupled to the gate of the drive transistor 130, and the second terminal of the first capacitor 137 may be coupled to the second source/drain of the drive transistor 130. Alternatively, the second terminal of the first capacitor 137 may be coupled to a DC power source to receive a fixed voltage (or referred to as a third preset voltage). The voltage provided by the DC power source may be different from the first operating voltage ARVDD. The second capacitor 138 is coupled between the gate of the drive transistor 130 and the node N. The gate of the setting transistor 135 may receive a lighting signal EM. The first source/drain of the setting transistor 135 may receive a reference voltage VREF. The second source/drain of the setting transistor 135 may be coupled to the node N. During a display period, the setting transistor 135 is turned on to transmit the reference voltage VREF to the node N. The data transistor 136 is coupled to the node N, and transmits a data signal DT to the node N according to the scan signal Sn. During a write period, the data transistor 136 is turned on to transmit the data signal DT to the node N.

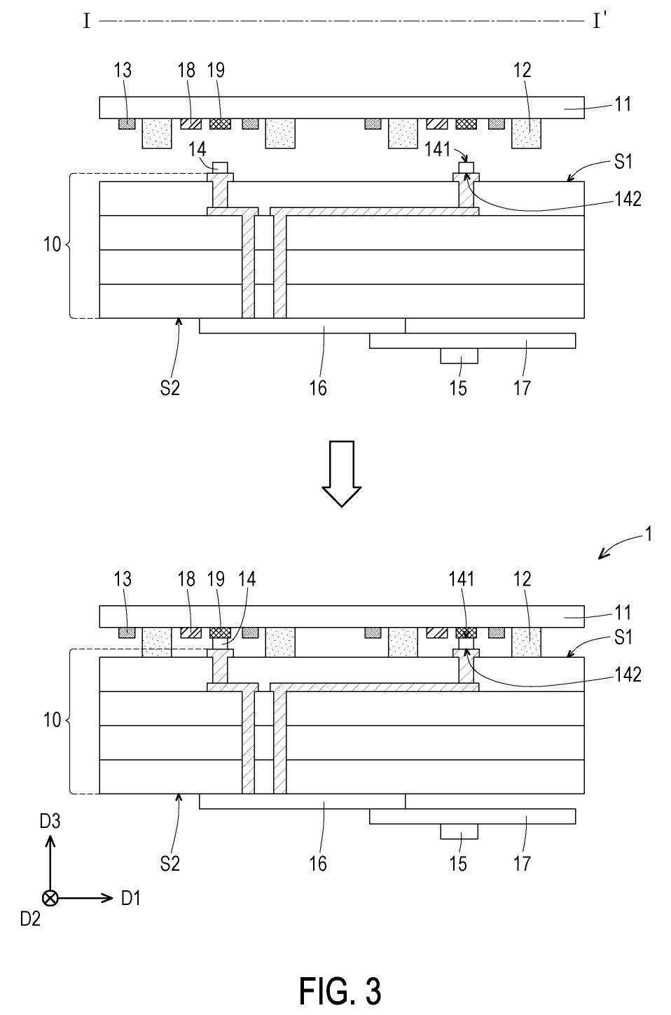

Referring to FIG. 1 or FIG. 3, the internal electrical connection structure 14 may be configured to electrically connect the first substrate 11 and the circuit substrate 10. The internal electrical connection structure 14 may be a conductive pillar, such as a copper pillar, a tin pillar, but not limited thereto. The internal electrical connection structure 14 may be disposed on the circuit substrate 10 first, and then the first substrate 11 and the circuit substrate 10 are assembled. The circuit substrate 10 includes a first surface S1 and an opposite second surface S2. The internal electrical connection structure 14 may be disposed on the first surface S1, and the electronic device 1 may further include an integrated circuit 15 disposed on the second surface S2.

As shown in FIG. 3, the electronic device 1 may optionally include a flexible printed circuit 16 and a carrier board 17, in which the integrated circuit 15 may be disposed on the carrier board 17, the flexible printed circuit board 16 may be disposed on the second surface S2, and the integrated circuit 15 may be electrically connected to the circuit substrate 10 sequentially through the carrier board 17 and the flexible printed circuit board 16. Alternatively, the electronic device 1 may omit the carrier board 17, the integrated circuit 15 may be disposed on the flexible printed circuit board 16 and the integrated circuit 15 may be electrically connected to the circuit substrate 10 through the flexible printed circuit board 16. In some embodiments, the integrated circuit 15 may be disposed on the second surface S2 and the integrated circuit 15 may be electrically connected to the circuit substrate 10.

As shown in FIG. 1 or FIG. 3, the electronic device 1 may optionally include a gate drive circuit 18 electrically connected to the drive unit 13. The gate drive circuit 18 may be disposed on the first substrate 11. The electronic device 1 may include a plurality of gate drive circuits 18 extending along the direction D2 and arranged along the direction D1, but not limited thereto.

As shown in FIG. 1 or FIG. 3, the electronic device 1 may further include a plurality of contact points 19 disposed overlapping with the internal electrical connection structures 14 in the direction D3. The contact points 19 may electrically connect the gate drive circuits 18 and the drive units 13 through the wiring layer in the first substrate 11. The contact points 19 may be configured to transmit, for example, a lighting signal EM, a reset signal RST, a data signal DT, a first operate voltage ARVDD, and/or a second operate voltage ARVSS, but not limited thereto.

As shown in FIG. 3, the electronic element 12, the drive unit 13, the gate drive circuit 18, and the contact points 19 may be disposed on a surface of the first substrate 11 facing the circuit substrate 10, the internal electrical connection structure 14 may be disposed on a surface of the circuit substrate 10 facing the first substrate 11 (the first surface S1), and the second conductive terminal 142 of the internal electrical connection structure 14 may physically contact the circuit substrate 10. After the first substrate 11 and the circuit substrate 10 are assembled, the electronic element 12, the drive unit 13, the internal electrical connection structure 14, the gate drive circuit 18, and the contact points 19 may be disposed between the first substrate 11 and the circuit substrate 10, and the contact points 19 may physically contact the first conductive terminal 141 of the internal electrical connection structure 14. In embodiments where the electronic element 12 is a light-emitting component, the first substrate 11 is a light-transmitting substrate, such that light emitted by the light-emitting component may penetrate the first substrate 11 and emit from the electronic device 1.

FIG. 3 schematically illustrates that the distance in the direction D3 after the first substrate 11 and the circuit substrate 10 are assembled is substantially equal to the thickness of the electronic element 12. In some embodiments not illustrated, the electronic device 1 may further include frame sealant, a spacer, and/or other mechanical components for fixing the first substrate 11 and the circuit substrate 10, and the distance in the direction D3 after the first substrate 11 and the circuit substrate 10 are assembled may be adjusted by controlling the thickness of the frame sealant, the spacer, and/or the mechanical components. In embodiments where the electronic element 12 is disposed between the first substrate 11 and the circuit substrate 10, the distance may be greater than or equal to the thickness of the electronic element 12. In embodiments where the first substrate 11 is disposed between the electronic element 12 and the circuit substrate 10, the distance may be greater than, equal to, or less than the thickness of the electronic element 12. The description of this paragraph applies to all the following embodiments.

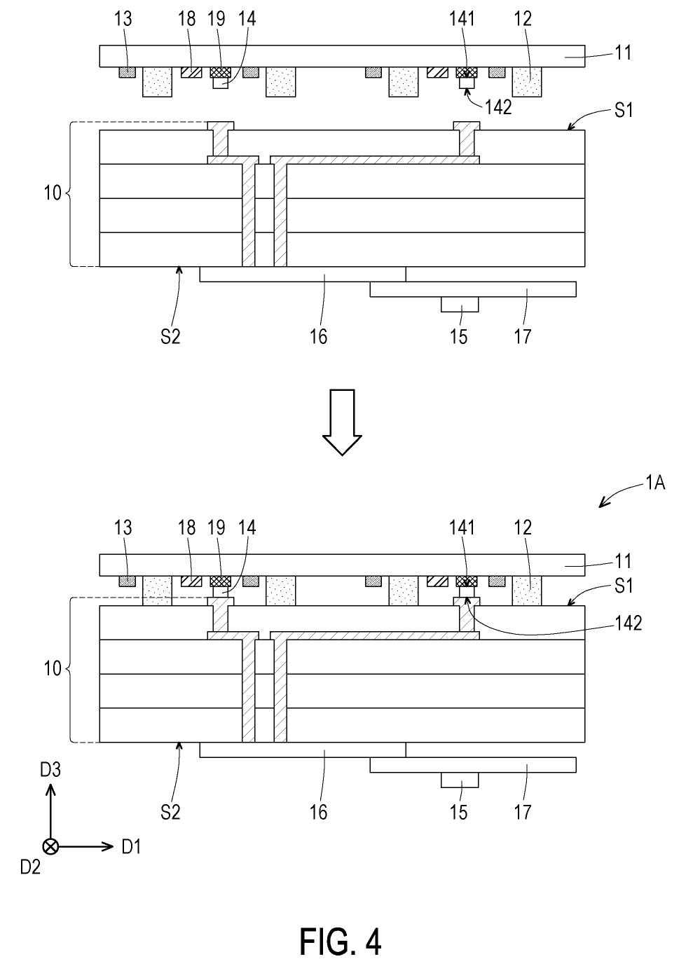

In some embodiments, as shown in an electronic device 1A in FIG. 4, before the first substrate 11 and the circuit substrate 10 are assembled, the internal electrical connection structure 14 may be disposed on the contact points 19, and the first conductive terminal 141 of the internal electrical connection structure 14 may physically contact the contact points 19. The second conductive terminal 142 of the internal electrical connection structure 14 may physically contact the circuit substrate 10 after the first substrate 11 and the circuit substrate 10 are assembled.

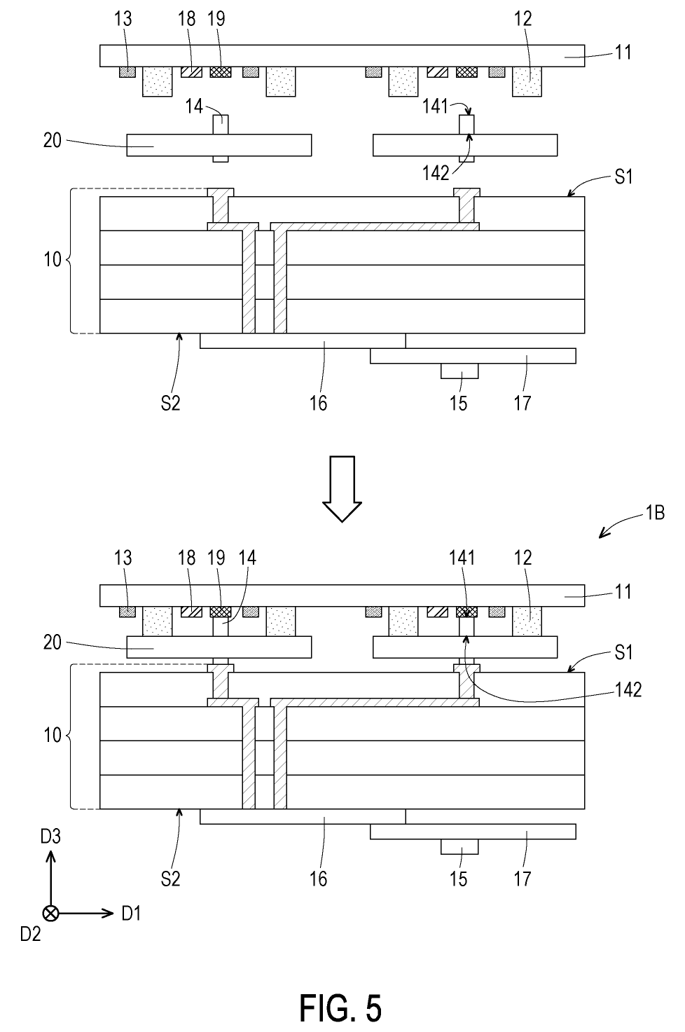

In some embodiments, as shown in FIG. 5, an electronic device 1B may further include a second substrate 20 disposed between the first substrate 11 and the circuit substrate 10, and the internal electrical connection structure 14 may be disposed on the second substrate 20. Before the first substrate 11 and the circuit substrate 10 are assembled, the internal electrical connection structure 14 may be disposed on the surface of the second substrate 20 facing the first substrate 11, and the second conductive terminal 142 of the internal electrical connection structure 14 may physically contact the second substrate 20. After the first substrate 11 and the circuit substrate 10 are assembled, the first conductive terminal 141 of the internal electrical connection structure 14 may physically contact the contact points 19, and the contact points 19 may be electrically connected to the integrated circuit 15 sequentially through the internal electrical connection structure 14, the second substrate 20, the circuit substrate 10, the flexible printed circuit board 16, and the carrier board 17. The second substrate 20 may be an interposer substrate including a wiring layer (not illustrated). Or, the electronic device 1B may omit the carrier board 17, the integrated circuit 15 may be disposed on the flexible printed circuit board 16 and the integrated circuit 15 may be electrically connected to the circuit substrate 10 through the flexible printed circuit board 16. In some embodiments, the integrated circuit 15 may be disposed on the second surface S2 and the integrated circuit 15 may be electrically connected to the circuit substrate 10.

In some embodiments not illustrated, in addition to the frame adhesive, the spacer, and/or the mechanical components used to fix the first substrate 11 and the circuit substrate 10, the electronic device 1B may further include frame adhesive, a spacer, and/or other mechanical components used to fix the second substrate 20 and the circuit substrate 10. The description of this paragraph applies to all the following embodiments including the second substrate 20.

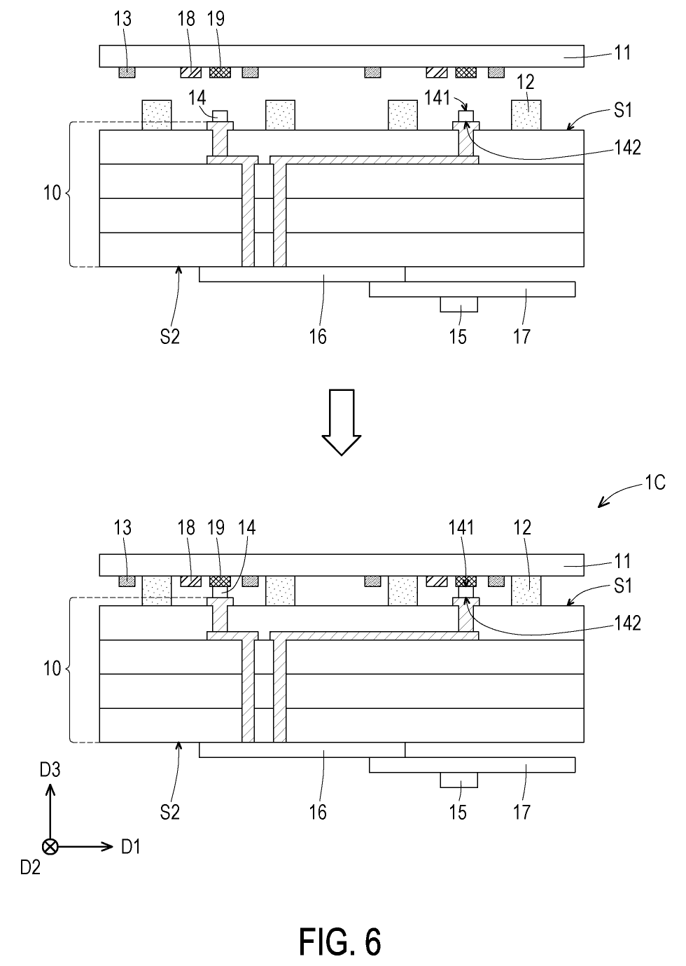

In some embodiments, as shown in an electronic device 1C in FIG. 6, before the first substrate 11 and the circuit substrate 10 are assembled, the electronic element 12 may be disposed on the circuit substrate 10 and electrically connected to the circuit substrate 10. After the first substrate 11 and the circuit substrate 10 are assembled, the electronic element 12 may be electrically connected to the drive unit 13 sequentially through the circuit substrate 10, the internal electrical connection structure 14, the contact points 19, and the first substrate 11.

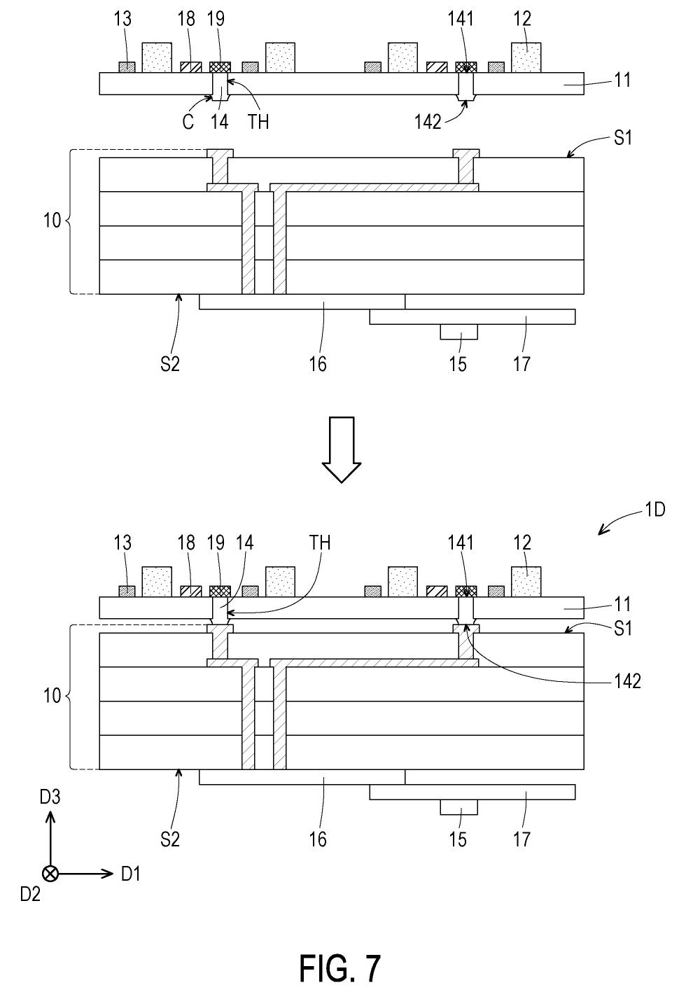

In some embodiments, as shown in an electronic device 1D in FIG. 7, the first substrate 11 may be disposed between the electronic element 12 and the circuit substrate 10 and between the drive unit 13 and the circuit substrate 10, and the internal electrical connection structure 14 may penetrate through the first substrate 11. Through holes TH may be formed in the first substrate 11 by laser drilling, etching, or other patterning methods, and then the internal electrical connection structure 14 may be formed in the through holes TH. The thickness of the internal electrical connection structure 14 may be greater than the thickness of the first substrate 11, such that the internal electrical connection structure 14 protrudes beyond the through holes TH. Liquid conductive material may be filled into the through holes TH by printing. Since the liquid conductive material may overflow beyond the through holes TH before curing, the resulting internal electrical connection structure 14 may protrude beyond the through holes TH, and the internal electrical connection structure 14 outside the through holes TH may have curved sidewalls C. The thickness of the internal electrical connection structure 14 may be less than or equal to the thickness of the first substrate 11 (not illustrated), in which case an electrical connection portion (not illustrated) needs to be specially designed on the circuit substrate 10 to electrically connect with the internal electrical connection structure 14.

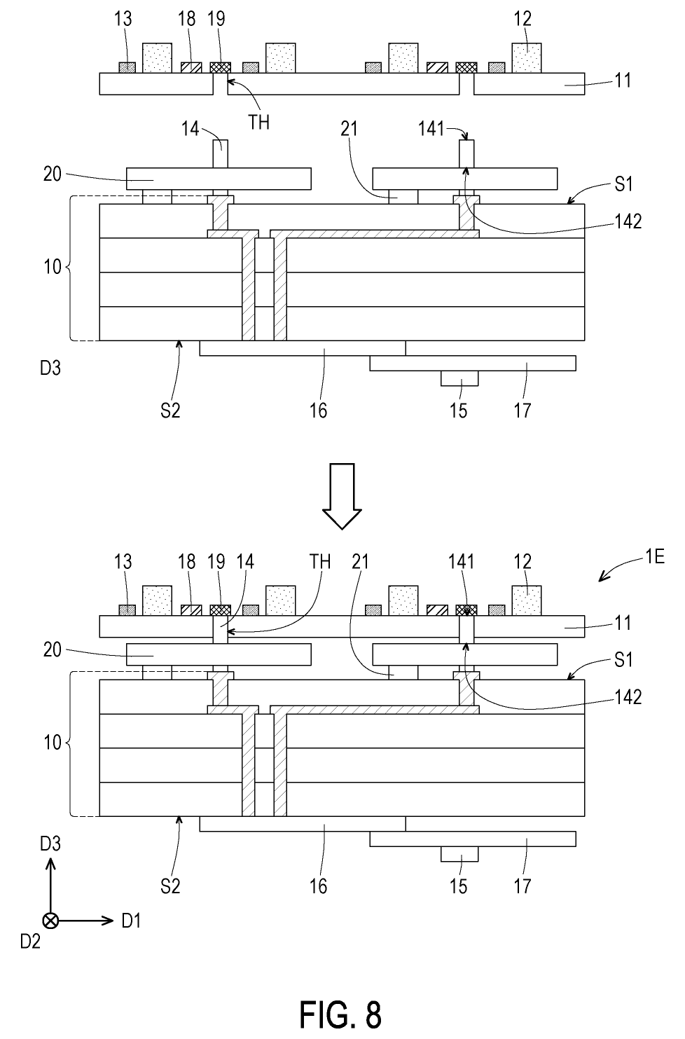

In some embodiments, as shown in FIG. 8, an electronic device 1E may further include the second substrate 20 disposed between the first substrate 11 and the circuit substrate 10, and the internal electrical connection structure 14 may electrically connect to the circuit substrate 10 through the second substrate 20. The electronic element 12, the drive unit 13, the gate drive circuit 18, and the contact points 19 may be disposed on the surface of the first substrate 11 facing the circuit substrate 10, and the first substrate 11 may be formed with the through holes TH overlapping with the contact points 19. Before the first substrate 11 and the circuit substrate 10 are assembled, the internal electrical connection structure 14 may be disposed on the surface of the second substrate 20 facing the first substrate 11, and the second conductive terminal 142 of the internal electrical connection structure 14 may physically contact the second substrate 20. After the first substrate 11 and the circuit substrate 10 are assembled, the internal electrical connection structure 14 is correspondingly disposed in the through holes TH, the first conductive terminal 141 of the internal electrical connection structure 14 may physically contact the contact points 19, and the contact points 19 may be electrically connected to the integrated circuit 15 sequentially through the internal electrical connection structure 14, the second substrate 20, the circuit substrate 10, the flexible printed circuit board 16, and the carrier board 17. The electronic device 1E may omit the carrier board 17, the integrated circuit 15 may be disposed on the flexible printed circuit board 16 and the integrated circuit 15 may be electrically connected to the circuit substrate 10 through the flexible printed circuit board 16. The integrated circuit 15 may be disposed on the second surface S2 and the integrated circuit 15 may be electrically connected to the circuit substrate 10. The electronic device 1E may further include an integrated circuit 21 disposed on the second substrate 20. In some embodiments, the second substrate 20 may be disposed between the integrated circuit 21 and the internal electrical connection structure 14. For example, the internal electrical connection structure 14 may be disposed on the surface of the second substrate 20 facing the first substrate 11, and the integrated circuit 21 may be disposed on the surface of the second substrate 20 facing the circuit substrate 10. The integrated circuit 21 may share part of the operations and/or functions of the integrated circuit 15, thereby helping to reduce heat concentration, enhance computing speed, and/or enable further miniaturization of the integrated circuit.

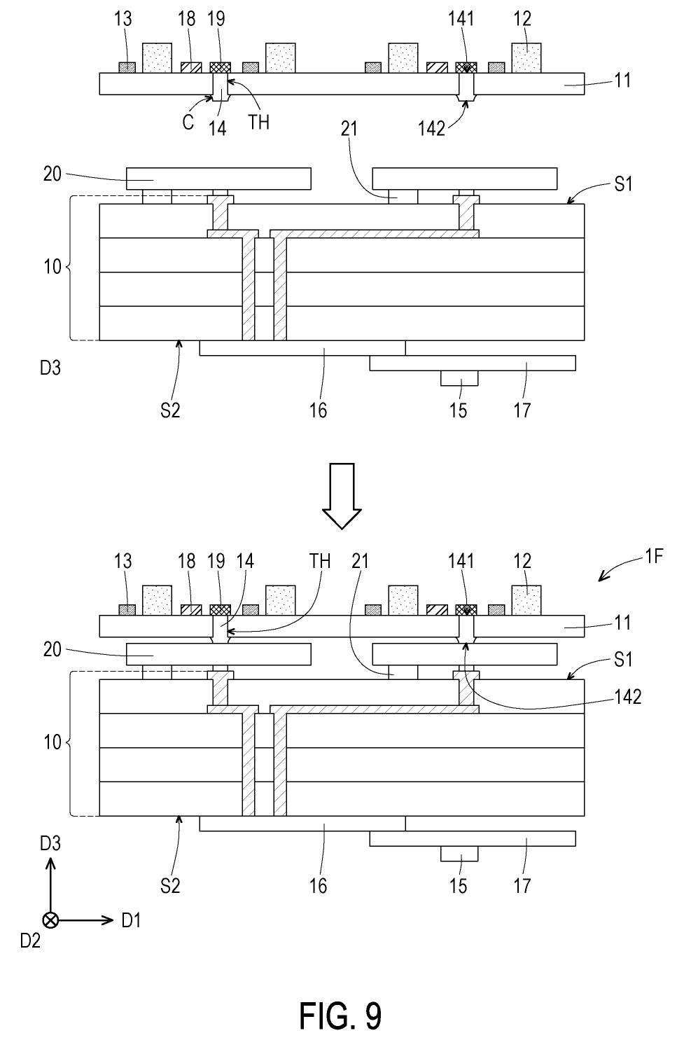

In some embodiments, as shown in an electronic device 1F in FIG. 9, before the first substrate 11 and the circuit substrate 10 are assembled, the internal electrical connection structure 14 may be disposed in the through holes TH, and the first conductive terminal 141 of the internal electrical connection structure 14 may physically contact the contact points 19. The second conductive terminal 142 of the internal electrical connection structure 14 may physically contact the second substrate 20 after the first substrate 11 and the circuit substrate 10 are assembled, and may be electrically connected to the integrated circuit 15 sequentially through the internal electrical connection structure 14, the second substrate 20, the circuit substrate 10, the flexible printed circuit board 16, and the carrier board 17. In some embodiments, the electronic device 1F may omit the carrier board 17, in which the integrated circuit 15 may be disposed on the flexible printed circuit board 16 and the integrated circuit 15 may be electrically connected to the circuit substrate 10 through the flexible printed circuit board 16. In some embodiments, the integrated circuit 15 may be disposed on the second surface S2 and the integrated circuit 15 may be electrically connected to the circuit substrate 10.

Alternatively, although not illustrated, multiple electronic devices 1 as shown in FIG. 3 may be tiled together, multiple electronic devices 1A as shown in FIG. 4 may be tiled together, multiple electronic devices 1B as shown in FIG. 5 may be tiled together, multiple electronic devices 1C as shown in FIG. 6 may be tiled together, multiple electronic devices 1D as shown in FIG. 7 may be tiled together, multiple electronic devices 1E as shown in FIG. 8 may be tiled together, multiple electronic devices 1F as shown in FIG. 9 may be tiled together, or multiple ones of the electronic devices as shown in FIG. 3 to FIG. 9 may be tiled together to form a tiled device, thereby expanding the size of the electronic device.

In summary, in the embodiments of the disclosure, the internal electrical connection structure may be disposed to provide electrical connection methods between multiple substrates. Furthermore, by respectively disposing different components of the electronic device on multiple substrates, the disclosure helps address the problem of insufficient routing layout space in electronic devices (for example, small-size panels), thereby facilitating the miniaturization of the area of the electronic device or facilitating the formation of the tiled device.

What is claimed is:

1. An electronic device, comprising:
a circuit substrate;
a first substrate overlapping the circuit substrate;
an electronic element disposed on the first substrate;
a drive unit disposed on the first substrate and electrically connected to the electronic element; and
an internal electrical connection structure disposed between the circuit substrate and the first substrate and comprising a first conductive terminal and a second conductive terminal, wherein the first conductive terminal and the second conductive terminal are electrically connected to the first substrate and the circuit substrate respectively.

2. The electronic device as claimed in claim 1, further comprising:
a gate drive circuit electrically connected to the drive unit.

3. The electronic device as claimed in claim 2, wherein the gate drive circuit is disposed on the first substrate.

4. The electronic device as claimed in claim 2, wherein the gate drive circuit and the drive unit are both separated from the circuit substrate.

5. The electronic device as claimed in claim 1, wherein the circuit substrate comprises a first surface and a second surface opposite to the first surface, wherein the internal electrical connection structure is disposed on the first surface, and the electronic device further comprises:
an integrated circuit disposed on the second surface.

6. The electronic device as claimed in claim 1, further comprising:
a second substrate disposed between the first substrate and the circuit substrate, and the internal electrical connection structure is disposed on the second substrate.

7. The electronic device as claimed in claim 6, wherein the drive unit is separated from the second substrate.

8. The electronic device as claimed in claim 1, wherein the electronic element, the drive unit, and the internal electrical connection structure are disposed between the first substrate and the circuit substrate, the electronic element is a light-emitting component, and the first substrate is a light-transmitting substrate.

9. The electronic device as claimed in claim 1, wherein the first substrate is disposed between the electronic element and the circuit substrate and between the drive unit and the circuit substrate, and the internal electrical connection structure penetrates through the first substrate.

10. The electronic device as claimed in claim 9, wherein the internal electrical connection structure protrudes beyond a through hole of the first substrate.

11. The electronic device as claimed in claim 10, wherein the internal electrical connection structure outside the through hole has a curved sidewall.

12. The electronic device as claimed in claim 11, wherein the curved sidewall and the electronic element are located on opposite sides of the first substrate respectively.

13. The electronic device as claimed in claim 9, further comprising:
a second substrate disposed between the first substrate and the circuit substrate, and the internal electrical connection structure electrically connects to the circuit substrate through the second substrate.

14. The electronic device as claimed in claim 13, further comprising:
an integrated circuit disposed on the second substrate.

15. The electronic device as claimed in claim 13, wherein the second substrate is disposed between the integrated circuit and the internal electrical connection structure.

16. The electronic device as claimed in claim 13, wherein the integrated circuit is disposed between the second substrate and the circuit substrate.

17. The electronic device as claimed in claim 13, wherein the circuit substrate includes a first surface and a second surface opposite to the first surface, wherein the second substrate is disposed on the first surface, and the electronic device further comprises:
another integrated circuit disposed on the second surface.

18. The electronic device as claimed in claim 1, further comprising:
a contact point disposed on the first substrate and disposed overlapping with the internal electrical connection structure, wherein the contact point electrically connects the drive unit through the first substrate.

19. The electronic device as claimed in claim 18, wherein the first conductive terminal electrically connects the drive unit through the contact point and the first substrate.

20. The electronic device as claimed in claim 1, wherein the internal electrical connection structure is a conductive pillar.
